(19) United States
(12) Patent Application Publication
(10) Pub. No.: US 2005/0236616 A1
(43) Pub. Date: Oct. 27, 2005

(54) Reliable semiconductor structure and method for fabricating

(76) Inventors: Horng-Huei Tseng, Hsinchu (TW); Chung-Hu Ge, Hsintien City (TW); Chao-Hsiung Wang, Taipei City (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/831,981

(22) Filed: Apr. 26, 2004

(51) Int. Cl. H01L 21/66

(52) U.S. Cl. 257/48

(57) ABSTRACT

A reliable semiconductor structure and its fabrication method. Active regions and/or scribe lines on a semiconductor substrate are configured along a crack resistant crystalline direction. Thermal cracking due to the abrupt temperature ramp of rapid thermal processing can be avoided.

### BACKGROUND

The present invention relates to semiconductor manufacturing, and particularly to a reliable semiconductor structure and a fabrication method thereof.

Semiconductor device geometries have dramatically decreased in size since such devices were first introduced several decades ago. Modern wafer fabrication plants are routinely producing devices having 0.13 μm and even 0.09 μm feature sizes, and tomorrow's plants will soon be producing devices with even smaller geometries. The reduction in size of device geometries, however, introduces new challenges that need to be overcome.

High quality field effect transistors (FETs) are almost exclusively formed on (100) semiconductor wafer surface under present technology. Conventionally, in a semiconductor integrated circuit device using a silicon substrate, an active region of the MOSFET is configured to be parallel to a <110> crystalline direction of the silicon substrate. Scribe lines are also configured to be parallel to the <110> direction; therefore, the substrate can be easily split into chips by cleaving the substrate.

As device features continue to be aggressively scaled down, the conventional configuration along the <110> direction becomes problematic and impacts yield. Modern semiconductor technology employs rapid thermal processing (RTP) tools to activate the source/drain of FET transistors to achieve high performance. As the feature size is reduced, RTP with a shorter thermal cycle is imperative in achieving an ultra-shallow junction as well a uniform interface between source/drain regions and silicide in salicide processes. A shorter thermal cycle means higher temperature ramp rate. Unfortunately, according to the present inventors' investigation, the mechanical strength along the <110> crystalline direction of a silicon substrate is insufficient to prevent thermal generated cracks due to the abrupt temperature change required for achieving feature sizes below 0.1 micron. Serious cracking was found along the <110> crystalline direction of the substrate on scribe lines and active regions after rapid thermal processing. Moreover, the industry is moving to a larger wafer size to reduce manufacturing cost per die. The thermal crack problem, however, prohibits the continuous evolution of increasing the wafer size, because the larger the wafer, the more easily the wafer cracks.

Accordingly, it is desirable to provide a semiconductor structure capable of preventing cracks during RTP for fabricating devices having a feature size below 0.1 micron.

U.S. Pat. No. 6,639,280 discloses a semiconductor chip in which the device channel direction is along <100>, rather than <110> as in the conventional art. A laminated substrate is formed by laminating a device forming substrate and a supporting substrate. Scribe lines are formed along a <110> crystalline direction of the supporting substrate such that the substrate is easily cleaved. The thermal crack along <110> direction caused by RTP is still an issue. Moreover, two single crystalline substrates are required to form a laminated substrate with different crystallographic orientations, which inevitably incurs more cost and decreases throughput.

### SUMMARY

A broad object of the invention is to provide a semiconductor device having a feature size below 0.1 micron and its method of fabrication.

Another object of the invention is to provide a reliable semiconductor structure and its fabrication method, capable of preventing crack in the rapid thermal processing required for achieving ultra-shallow junctions.

A further object of the invention is to provide a reliable semiconductor structure and its fabrication method that provide improved crack resistance to accommodate the use of lager wafer size.

To achieve the above and other objects, active regions and/or scribe lines are configured at a slant to a <110> crystalline direction of the semiconductor substrate such that the substrate is more crack resistant.

According to one aspect of the invention, active regions are configured along a direction where the substrate is crack resistant. A single crystalline semiconductor substrate is provided and active regions are defined on the substrate to extend along a crystalline direction at a slant to a <110> crystalline direction of the substrate. Semiconductor devices are formed on the substrate by processes including rapid thermal processing.

According to another aspect of the invention, scribe lines are configured along a direction where the semiconductor substrate is crack resistant. A single crystalline semiconductor substrate is provided. Semiconductor devices are formed on the substrate within a plurality of die areas divided by scribe lines extending along a crystalline direction at a slant to a <110> crystalline direction of the semiconductor substrate. The formation of the devices comprises a step of subjecting the substrate to rapid thermal processing.

According to the invention, the active regions and the scribe lines may extend substantially along a <100> crystalline direction of the substrate, which intersects the <110> direction at a right angle. Alternatively, the active regions and the scribe lines may extend along a direction which lies at angle of about 25-40 degrees to the <110> direction. In the present invention, the active regions, the scribe lines and a channel direction of the device may be not parallel with one another although they are typically parallel in the conventional art.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 shows a plane view of a conventional semiconductor substrate.

FIG. 2 shows a plane view of a semiconductor structure according to an embodiment of the invention, in which active regions are extended at a slant to a <110> crystalline direction of the semiconductor substrate.

FIG. 3 shows a plane view of a semiconductor structure according to another embodiment of the invention, in which scribe lines are extended at a slant to a <110> crystalline direction of the semiconductor substrate.

### DESCRIPTION

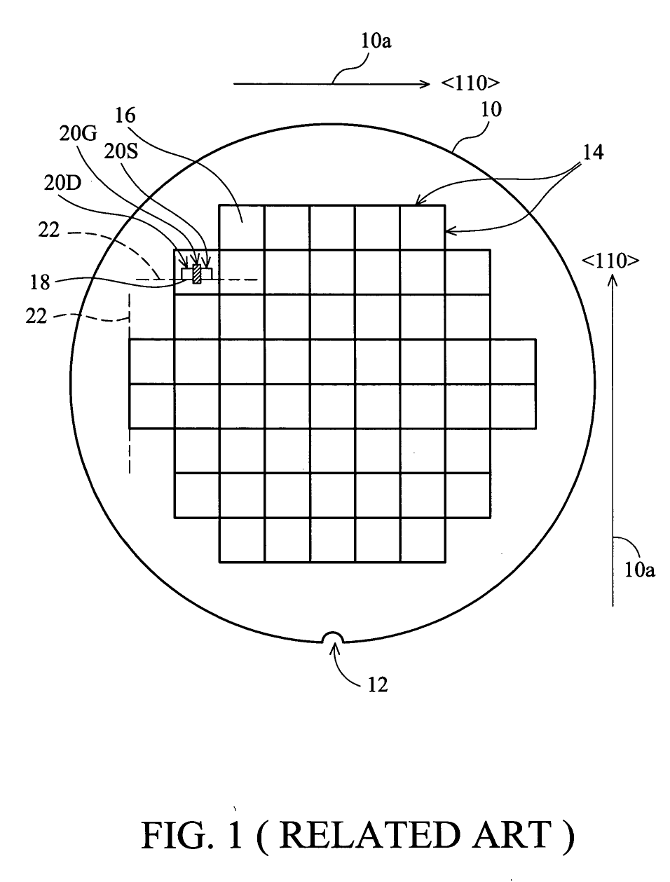

FIG. 1 shows a plane view of a conventional semiconductor wafer 10 with a notch 12 to indicate a <110> crystalline direction 10a of the wafer. Note that since the crystalline direction expressed by <110> includes all of the crystalline directions that are equivalent to [110], the direction that intersects perpendicularly with <110> direction 10a is also expressed as <110>. A plurality of chip areas 16 are defined on the wafer by latticed scribe lines 14, which are parallel to the <110> direction 10a of the wafer. Within the chip area 16, a field effect transistor consisting of a gate electrode 20G, a source region 20S, and a drain region 20D, is formed on an active region 18 substantially extending along the <110> direction 10a. This conventional semiconductor structure cracks along the <110> direction as indicated by dashed lines 22 when subjected to rapid thermal processing, particularly when a flash anneal with a temperature ramp rate exceeding 400° C./sec is performed.

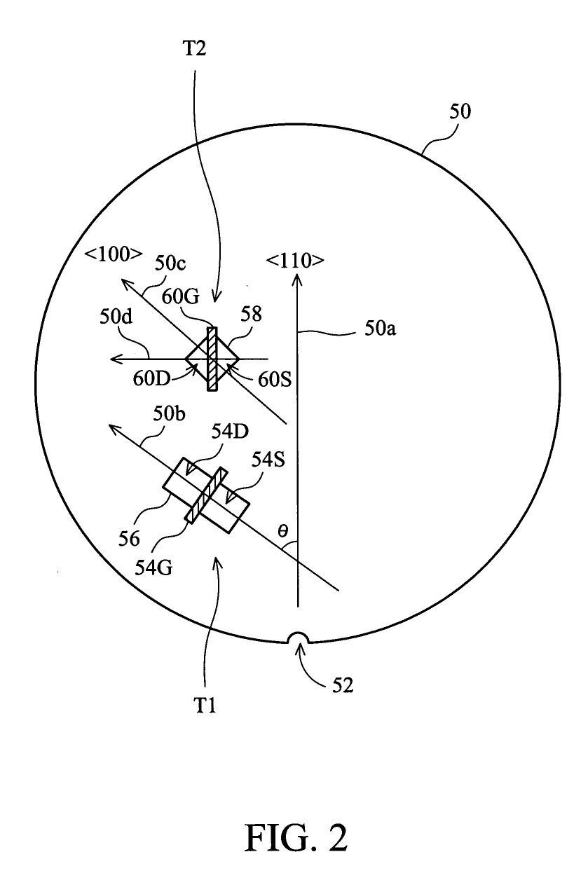

Referring now to FIG. 2, a crack-resistant semiconductor structure according to an embodiment of the invention will be described. FIG. 2 shows a single crystalline semiconductor substrate 50 with a notch 52 formed at the edge of the substrate representing a <110> crystalline direction 50a of substrate 50. An orientation flat may be formed instead of the notch, and the surface orientation of the substrate 50 is [100]. The semiconductor substrate 50 is preferably a single crystalline silicon wafer with a diameter greater than 8 inches. In addition to single crystalline silicon wafer, the semiconductor substrate 50 could be a laminated substrates or silicon-on-insulator substrate. The semiconductor substrate 50 may have a thickness from about 550 μm to 750 μm or from about 700 μm to 900 μm. Additionally, the semiconductor substrate 50 may comprises defective crystal structure near its surface to form strained channel devices, such as high mobility silicon or SiGe strained channel transistors.

A plurality of semiconductor devices are formed on the semiconductor substrate 50. The devices may include one or more transistors, electrically programmable read only memory (EPROM) cells, electrically erasable programmable read only memory (EEPROM) cells, dynamic random access memory (DRAM) cells and/or other semiconductor devices. Each of which may be formed by various known methods, such as photolithography, film formation, etching, ion implantation and other process techniques. In order to simplify the drawing, only a field effect transistor T1 is shown and the size of the transistor is exaggerated for illustrative purposes.

As an important feature of the invention, the transistor T1 is formed on an active region 56 which extends along a crystalline direction 50b where the substrate is resistant to thermal cracking. The active region can be defined by conventional isolation techniques such as shallow trench isolation (STI) methods. The transistor T1 consists of a gate electrode 54G crossing the active region 56, and source/drain regions 54S/54D which are configured on both sides of the gate electrode 54G. As shown in FIG. 2, the active region 56 is extended along a direction 50b which lies at angle θ to the <110> direction 50a of the semiconductor substrate. The slant angle θ can be 45 degrees such that the active region is configured along a <100> crystalline direction of the substrate 50. Alternatively, the same effect may be acquired by making the slant of the angle θ between about 25-40 degrees.

According to the invention, the transistor T1 preferably features a channel length of 90 nm or less and a source/drain junction depth of 43 nm or less. Various known rapid thermal processing systems can be employed to achieve the ultra-shallow junction for sub-90 nm MOSFETs, including those using heat sources, such as, a tungsten-halogen lamp with a temperature ramp rate exceeding 200° C./sec, a laser. Preferably, a noble gas long-arc lamp with a temperature ramp rate exceeding 10,000° C./sec is employed.

Still referring to FIG. 2, another feature of the invention is illustrated by transistor T2. While the channel direction and the active region are typically parallel in the conventional art, the invention is not limited thereto. The transistor T2, consisting of a gate electrode 60G and source/drain regions 60S/60D, is formed on an active region extending long a <100> direction 50b of the substrate 50 while the channel region of the transistor T2 extends along a <110> direction 50d. Namely, as long as the active region is configured along a crack-resistant direction, the channel direction need not be substantially parallel with the active region to maintain the crack resistant properties.

Note that, although the above embodiment was explained with reference to a semiconductor wafer, the present invention is not limited thereto and the substrate 50 may be in form of an individual semiconductor chip.

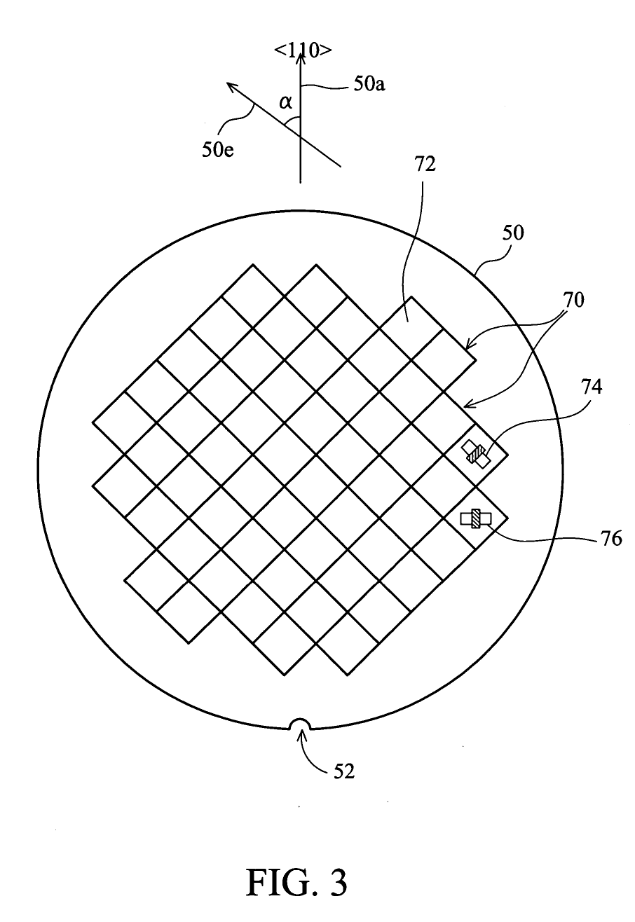

FIG. 3 shows a plane view of a crack-resistant semiconductor structure according to another embodiment of the invention. A plurality of die areas 72 are defined by latticed scribe lines 70 on the single crystalline semiconductor substrate 50. The widths of the scribe lines are between about 60 μm and 200 μm. Each of the scribe lines is extended along a direction 50e at a slant to the <110> crystalline direction 50a of the semiconductor substrate to prevent thermal cracks. As shown in FIG. 3, the direction 50e lies at an angle a to the <110> crystalline direction 50a. The slant of the angle a can be 45 degrees such that the scribe lines 70 are extended to a <100> crystalline direction of the substrate 50. Additionally, the same effect can be achieved by making the slant of the angle a between about 25-40 degrees.

In this embodiment, the active region within the die area 72 may be configured along a direction substantially parallel to scribe lines 70, such as illustrated by active region 74. In such a case, both the scribe lines and the active regions are configured in a crack-resistant direction. Although less preferable, the active region may be unparallel to the direction of the scribe lines 70, such as illustrated by active region 76, which is extended along a <110> direction 50a as in the conventional art.

In the above-described embodiments, active regions and/or scribe lines on a semiconductor substrate are configured along a crack resistant crystalline direction. As such, thermal cracks due to the abrupt temperature ramp of rapid thermal processing can be avoided when making ultra-shallow junctions for sub-90 nm devices. Moreover, with the above-described configurations, the evolution of increased wafer size can continue while reducing crack issues.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art) . Therefore, the scope of the appended claims should be accorded the broadest interpretation so as to encompass all such modifications and similar arrangements.

1. A semiconductor structure, comprising:
a single crystalline semiconductor substrate thermally treated by rapid thermal processing; and
a device formed on an active region of the semiconductor substrate, wherein the active region is extended along a crystalline direction where the semiconductor substrate is resistant to thermal cracking.

2. The structure of claim 1, wherein the active region is extended along a direction at a slant to a <110> direction of the semiconductor substrate.

3. The structure of claim 1, wherein the active region is extended along a direction which lies at an angle of about 25-40 degrees to a <110> crystalline direction of the semiconductor substrate.

4. The structure of claim 1, wherein the active region is substantially extended along a <100> crystalline direction of the semiconductor substrate.

5. The structure of claim 4, wherein the device comprises a field effect transistor with a gate electrode and source/drain regions.

6. The structure of claim 5, wherein a channel length of the field effect transistor is less than 90 nm.

7. The structure of claim 5, wherein the source/drain regions have a junction depth less than 43 nm.

8. The structure of claim 5, wherein the semiconductor substrate is thermally treated by tungsten-halogen lamp.

9. The structure of claim 5, wherein the semiconductor substrate is thermally treated by tungsten-halogen lamp with a temperature ramp rate exceeding 200° C./sec.

10. The structure of claim 5, wherein the semiconductor substrate is thermally treated by noble gas long-arc lamp.

11. The structure of claim 5, wherein the semiconductor substrate is thermally treated by noble gas long-arc lamp with a temperature ramp rate exceeding 10,000° C./sec.

12. The structure of claim 5, wherein the semiconductor substrate is thermally treated by a laser source.

13. The structure of claim 1, wherein the semiconductor substrate has a (100) surface orientation.

14. The structure of claim 1, wherein the semiconductor substrate is a semiconductor wafer with a diameter greater than 8 inches.

15. The structure of claim 1, wherein the semiconductor substrate is a semiconductor wafer with a thickness from 550 μm to 750 μm.

16. The structure of claim 1, wherein the semiconductor substrate is a semiconductor wafer with a thickness from 700 μm to 900 μm.

17. The structure of claim 1, wherein the semiconductor substrate comprises silicon or germanium.

18. The structure of claim 1, wherein the semiconductor substrate comprises defective crystal structure near its surface.

19. The structure of claim 5, wherein a channel direction of the field effect transistor is substantially not parallel with the crystalline direction the active region extends.

20. The structure of claim 1, wherein the semiconductor substrate is a semiconductor chip.

21. The structure of claim 1, wherein the semiconductor substrate is a SOI (silicon-on-insulator) substrate.

22. A semiconductor structure, comprising:
a single crystalline semiconductor substrate thermally treated by rapid thermal processing, including a plurality of die areas divided by scribe lines extending along a crystalline direction where the semiconductor substrate exhibits resistance to thermal cracking.

23. The structure of claim 22, wherein the scribe lines are extended along a direction at a slant to a <110> crystalline direction of the semiconductor substrate.

24. The structure of claim 22, wherein the scribe lines are extended along a direction which lies at an angle of about 25-40 degrees to a <110> crystalline direction of the semiconductor substrate.

25. The structure of claim 22, wherein the scribe lines are extended along a <100> crystalline direction of the semiconductor substrate.

26. The structure of claim 22, further comprising an active region extending along a direction substantially unparallel with the scribe lines.

27. The structure of claim 26 , wherein the scribe lines are extended along a <100> crystalline direction of the semiconductor substrate, and the active region is extended along a <110> crystalline direction.

28. The structure of claim 22, wherein the semiconductor substrate has a (100) surface orientation.

29. The structure of claim 22, wherein the diameter of the semiconductor substrate is greater than 8 inches.

30. The structure of claim 22, wherein the semiconductor substrate is a semiconductor wafer with a thickness from 550 μm to 750 μm.

31. The structure of claim 22, wherein the semiconductor substrate is a semiconductor wafer with a thickness from 700 μm to 900 μm.

32. The structure of claim 22, wherein the semiconductor substrate comprises silicon or germanium.

33. The structure of claim 22, wherein the semiconductor substrate comprises defective crystal structure near its surface.

34. The structure of claim 22, wherein the semiconductor substrate is thermally treated by tungsten-halogen lamp.

35. The structure of claim 22, wherein the semiconductor substrate is thermally treated by tungsten-halogen lamp with a temperature ramp rate exceeding 200° C./sec.

36. The structure of claim 22, wherein the semiconductor substrate is thermally treated by noble gas long-arc lamp.

37. The structure of claim 22, wherein the semiconductor substrate is thermally treated by noble gas long-arc lamp with a temperature ramp rate exceeding 10,000° C./sec.

38. The structure of claim 22, wherein the semiconductor substrate is thermally treated by a laser source.

39. The structure of claim 22, wherein the widths of the scribe lines are between about 60 μm and 200 μm.

40. A method of fabricating a semiconductor structure, comprising:
providing a single crystalline semiconductor substrate;
defining active regions on the semiconductor substrate along a crystalline direction where the semiconductor substrate is resistant to thermal cracking; and
forming devices on the active regions, which comprises a step of subjecting the semiconductor substrate to rapid thermal processing.

41. The method of claim 40, wherein the active region is extended along a direction at a slant to a <110> direction of the semiconductor substrate.

42. The method of claim 40, wherein the active region is extended along a direction which lies at an angle of about 25-40 degrees to a <110> crystalline direction of the semiconductor substrate.

43. The method of claim 40, wherein the active region is substantially extended along a <100> crystalline direction of the semiconductor substrate.

44. The method of claim 43, wherein the device comprises a field effect transistor with a gate electrode and source/drain regions.

45. The method of claim 44, wherein a channel length of the field effect transistor is less than 90 nm.

46. The method of claim 44, wherein the source/drain regions have a junction depth less than 43 nm.

47. The method of claim 44, wherein the semiconductor substrate is thermally treated by tungsten-halogen lamp.

48. The method of claim 47, wherein the semiconductor substrate is thermally treated by tungsten-halogen lamp with a temperature ramp rate exceeding 200° C./sec.

49. The method of claim 44, wherein the semiconductor substrate is thermally treated by noble gas long-arc lamp.

50. The method of claim 49, wherein the semiconductor substrate is thermally treated by noble gas long-arc lamp with a temperature ramp rate exceeding 10,000° C./sec.

51. The method of claim 44, wherein the semiconductor substrate is thermally treated by a laser source.

52. The method of claim 40, wherein the semiconductor substrate has a (100) surface orientation.

53. The method of claim 40, wherein the semiconductor substrate is a semiconductor wafer with a diameter greater than 8 inches.

54. The method of claim 40, wherein the semiconductor substrate is a semiconductor wafer with a thickness from 550 μm to 750 μm.

55. The method of claim 40, wherein the semiconductor substrate is a semiconductor wafer with a thickness from 700 μm to 900 μm.

56. The method of claim 40, wherein the semiconductor substrate comprises silicon or germanium.

57. The method of claim 40, wherein the semiconductor substrate comprises defective crystal structure near its surface.

58. The method of claim 44, wherein a channel direction of the field effect transistor is substantially not parallel with the crystalline direction the active region extends.

59. The method of method 40, wherein the semiconductor substrate is a semiconductor chip.

60. The method of claim 40, wherein the semiconductor substrate is a SOI (silicon-on-insulator) substrate.

61. A method of fabricating a semiconductor structure, comprising:
providing a single crystalline semiconductor substrate;
forming devices on the semiconductor substrate within a plurality of die areas divided by scribe lines extending along a crystalline direction where the semiconductor substrate is resistant to thermal cracking, wherein the forming of the devices comprises a step of subjecting the substrate to rapid thermal processing.

62. The method of claim 61, wherein the scribe lines are extended along a direction at a slant to a <110> crystalline direction of the semiconductor substrate.

63. The method of claim 61, wherein the scribe lines are extended along a direction which lies at an angle of about 25-40 degrees to a <110> crystalline direction of the semiconductor substrate.

64. The method of claim 61, wherein the scribe lines are extended along a <100> crystalline direction of the semiconductor substrate.

65. The method of claim 61, further comprising an active region extending along a direction substantially unparallel with the scribe lines.

66. The method of claim 65, wherein the scribe lines are extended along a <100> crystalline direction of the semiconductor substrate, and the active region is extended along a <110> crystalline direction.

67. The method of claim 61, wherein the semiconductor substrate has a (100) surface orientation.

68. The method of claim 61, wherein the diameter of the semiconductor substrate is greater than 8 inches.

69. The method of claim 61, wherein the semiconductor substrate is a semiconductor wafer with a thickness from 550 μm to 750 μm.

70. The method of claim 61, wherein the semiconductor substrate is a semiconductor wafer with a thickness from 700 μm to 900 μm.

71. The method of claim 61, wherein the semiconductor substrate comprises silicon or germanium.

72. The method of claim 61, wherein the semiconductor substrate comprises defective crystal structure near its surface.

73. The method of claim 61, wherein the semiconductor substrate is thermally treated by tungsten-halogen lamp.

74. The method of claim 73, wherein the semiconductor substrate is thermally treated by tungsten-halogen lamp with a temperature ramp rate exceeding 200° C./sec.

75. The method of claim 61, wherein the semiconductor substrate is thermally treated by noble gas long-arc lamp.

76. The method of claim 75, wherein the semiconductor substrate is thermally treated by noble gas long-arc lamp with a temperature ramp rate exceeding 10,000° C./sec.

77. The method of claim 61, wherein the semiconductor substrate is thermally treated by a laser source.

78. The method of claim 61, wherein the widths of the scribe lines are between about 60 μm and 200 μm.
